(19) United States
(12) Patent Application Publication
(10) Pub. No.: US 2009/0032826 A1
(43) Pub. Date: Feb. 5, 2009

(54) MULTI-CHIP LIGHT EMITTING DIODE PACKAGE

(75) Inventors: Jerry Hu, Sijhih City (TW); Pao-Chi Chi, Sijhih City (TW); Albert Lin, Sijhih City (TW); Chia-Chi Liu, Sijhih City (TW)

Correspondence Address: BIRCH STEWART KOLASCH & BIRCH, PO BOX 747, FALLS CHURCH, VA, 22040-0747, US

(73) Assignee: Lustrous Technology Ltd., Sijhih City (TW)

(21) Appl. No.: 12/183,952

(22) Filed: Jul. 31, 2008

(30) Foreign Application Priority Data
Jul. 31, 2007 (TW) 96128027

(51) Int. Cl. H01L 33/00

(52) U.S. Cl. 257/88; 257/E33.063; 257/E33.058

(57) ABSTRACT

A multi-chip light emitting diode (LED) package having a plurality of LED chips, a substrate, and a plurality of conductive paste layers is provided. The substrate has at least two hollow areas with conductive patterns formed on a bottom surface thereon. The conductive paste layers are pasted on the bottom surfaces of the hollow areas respectively for fixing the LED chips and having the LED chips electrically connected to the conductive patterns. The LED chips in the different hollow areas are electrically connected in serial.

### BACKGROUND OF THE INVENTION

(1) Field of the Invention

This invention relates to a light emitting diode (LED) package, and more particularly relates to a multi-chip LED package.

(2) Description of the Prior Art

Light emitting diode LED) is a small-sized cold-light solid-state lighting capable of transforming electric power into optical power with high efficiency. The LED is mainly composed of a semiconductor p-n junction structure. When a potential is applied to the p-n junction structure, electrons and holes are driven by the potential toward the junction surface and combined to release photons.

FIG. 1 is a schematic cross-section view of a typical flip-chip LED package 10. As shown, the LED package 10 has an LED chip 12, a substrate 14, and a passivation layer 18. The substrate 14 has a concave 14a and a wiring pattern 17 formed thereon. The wiring pattern 17 may be fabricated by using metal deposition, lithography, and etching proceedings. The LED chip 12 is assembled in the concave 14a with a positive electrode and a negative electrode formed on an upper surface and a lower surface thereof The negative electrode is electrically connected to the electrode pattern 15a on the substrate 14 through the wiring pattern 17. The positive electrode is electrically connected to the electrode pattern 15b on the substrate 14 through a wire 16. If the LED chip 12 has both the positive and the negative electrodes formed on the lower surface thereof, the positive electrode may be electrically connected to the electrode pattern 15b by using another wiring pattern on the substrate 14. Finally, the passivation layer 18 is filled into the concave 14a and covers the LED chip 12 to prevent the intrusion of environmental particles and moisture.

It is a typical method to use conductive glue, such as silver conductive adhesion, to fix the LED chip 12 and electrically connect the LED chip 12 to the wiring pattern 17 as shown in FIG. 1. For a single-chip flip-chip LED package, it is an ideal method to use conductive glue to assemble the LED chip 12 on the substrate 14. However, referring to FIG. 2, for a multi-chip LED package 20, because the conductive glue is flowable, the conductive paste layers 26 pasted under every LED chips 22 may overlap with each other. As a result, the LED chips 22 designed to be electrically isolated may be wrongly connected by the overlapped conductive paste layers 26.

In order to prevent the conductive paste layers 26 from being overlapped, a typical method is to increase the interval between neighboring LED chips 22. However, this method increases the size of the LED package.

Accordingly, it is an important issue for the LED packaging industry to provide a multi-chip LED package capable of preventing the unwanted influence due to the flowable conductive paste layers when using conductive glue to fix LED chips.

### SUMMARY OF THE INVENTION

It is an object of the present invention to preventing the unpredictable bad influence toward circuit design for a multi-chip LED package because of the flowing of conductive glue.

A multi-chip light emitting diode (LED) package is provided in the present invention. The multi-chip LED package has a plurality of LED chips and a substrate. The substrate has a plurality of conductive patterns formed thereon. Each of the LED chips are assembled on the respected conductive pattern and electrically connected to the respected conductive pattern. The LED chips are connected in serial through the conductive patterns.

In an embodiment of the present invention, the substrate has at least two hollow areas, and each hollow area has at least two LED chips assembled therein and connected in parallel.

In an embodiment of the present invention, the substrate has at least two hollow areas, and each of the hollow areas has only one LED chip assembled therein.

### BRIEF DESCRIPTION OF THE DRAWINGS

The present invention will now be specified with reference to its preferred embodiment illustrated in the drawings, in which:

FIG. 1 is a cross-section view of a typical flip-chip LED package;

FIG. 2 is a schematic view of a typical multi-chip LED package showing the overlapped conductive paste layers;

FIG. 3 is a top view of a preferred embodiment of the multi-chip LED package in the present invention;

FIG. 3A is a cross-section view of the multi-chip LED package of FIG. 3 along cross section a-a;

FIG. 3B is a circuit diagram of the multi-chip LED package of FIG. 3;

FIG. 4 is a top view of another preferred embodiment of the multi-chip LED package in the present invention;

FIG. 4A is a cross-section view of the multi-chip LED package of FIG. 4 along cross section b-b; and

FIG. 4B is a circuit diagram of the multi-chip LED package of FIG. 4.

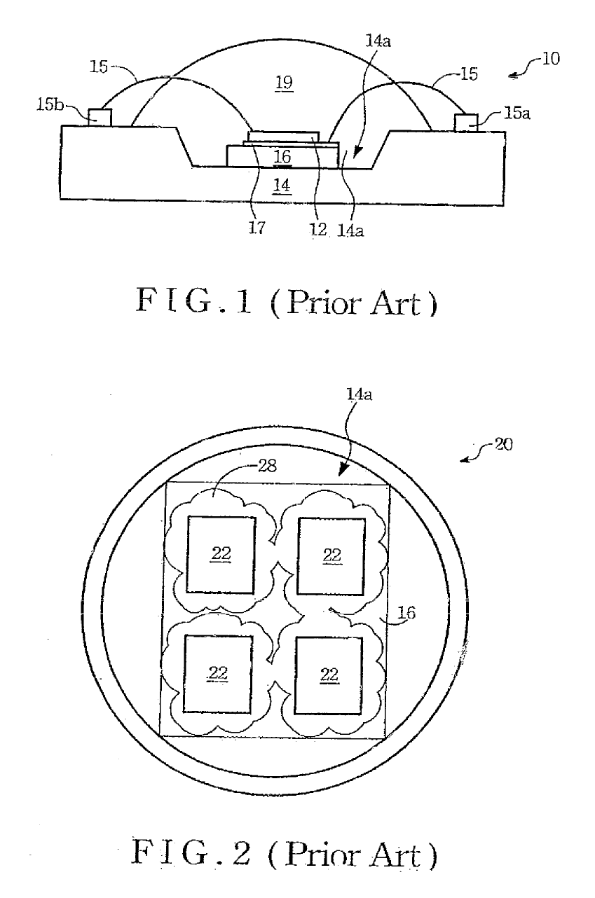

### DESCRIPTION OF THE PREFERRED EMBODIMENT

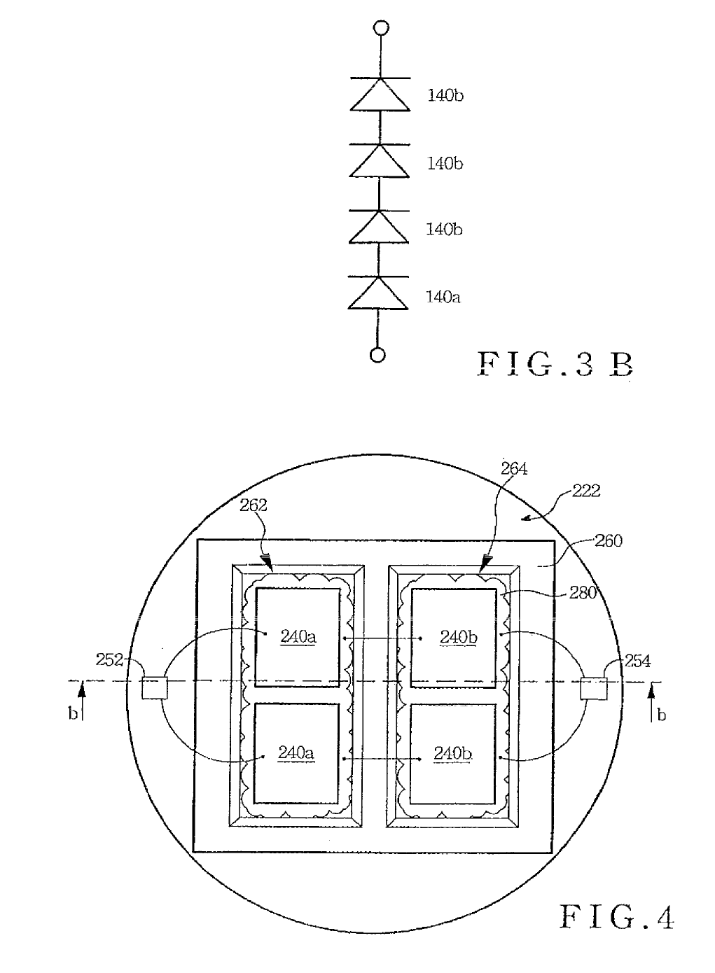

FIG. 3 is a top view of a preferred embodiment of the multi-chip LED package 100 in the present invention, and FIG. 3A is a cross-section view of the multi-chip LED package 100 in FIG. 3 along cross section a-a. As shown, the multi-chip LED package 100 has a board 120, a plurality of LED chips 140a,140b (four LED chips as shown in this figure), a substrate 160, a plurality of conductive paste layers 180, and a passivtion layer 190. The board 120 has a circular concave 122 thereon. The substrate 160 is located in the concave 122.

As a preferred embodiment, the board 120 may be formed of high thermal-conductivity metal, such as aluminum and etc., and the substrate 160 may be formed of semiconductor, such as silicon and etc. The substrate 160 has at least two hollow areas 162 formed thereon (four hollow areas 162 are shown in this figure). The hollow areas 162 are square in shape and evenly arranged on the substrate 160. The LED chips 140a,140b are assembled in the hollow areas 162.

The hollow area 162 has a conductive pattern 170 formed on a bottom surface thereof. The plurality of conductive paste layers 180 are formed on the bottom surface of the hollow areas 160 respectively for fixing respected LED chips 140a,140b. It is noted that the LED chip 140a,140b may be fixed on the conductive pattern 170 by eutectic bonding or using solder balls or gold balls if needed. The negative electrode of the LED chips 140a, 140b are electrically connected to the respected conductive pattern 170 on the bottom surface of the hollow area 162 by using the respected conductive paste layer 180 so as to have the LED chips 140a,140b flip-chip assembled on the substrate 160. The passivation layer 190 is deposited on the substrate and filled into the hollow areas 162 to prevent the LED chips 140a,140b from the intrusion of environmental particles and moisture.

Among the plurality of LED chips 140a,104b of the multi-chip LED package 100, the positive electrode of the LED chip 140a is electrically connected to a high level end 152 by using a wire 150, and the positive electrodes of the other LED chips 140b are electrically connected to the conductive patterns 170 in the neighboring hollow area 162 by using wires 150. Therefore, the LED chips 140a,140b located in the different hollow areas 162 are connected in serial. In addition, the conductive pattern 170 without connecting to the positive electrode of the LED chips 140a,140b (or the conductive pattern 170 in the hollow area 162 near the right upper corner of FIG. 3) is electrically connected to a low level end 154. The circuit diagram of the LED chips 140a,140b is shown in FIG. 3B.

Referring to FIG. 3A, flowing of the conductive paste layers 180 formed on the bottom surface of the hollow areas 162 are restricted by the sidewalls of the hollow areas 162 and would not overflow the hollow area 162. Thus, the negative electrodes of the neighboring LED chips 140a,140b can be perfectly isolated to prevent the uncontrollable flowing of the conductive paste layer 180 to result short circuit.

It is noted that the substrate 160 and the hollow areas 162 on the substrate are square in shape. However, the main idea of the present invention focuses on preventing the uncontrollable flowing of the conductive paste layer 180 by the formation of hollow areas 162. The shape of the substrate 160 and the hollow areas 162 should not be a limitation to the present invention. Thus, the substrate 160 and the hollow areas 162 may have a different shape, such as circular or rectangular according to the need.

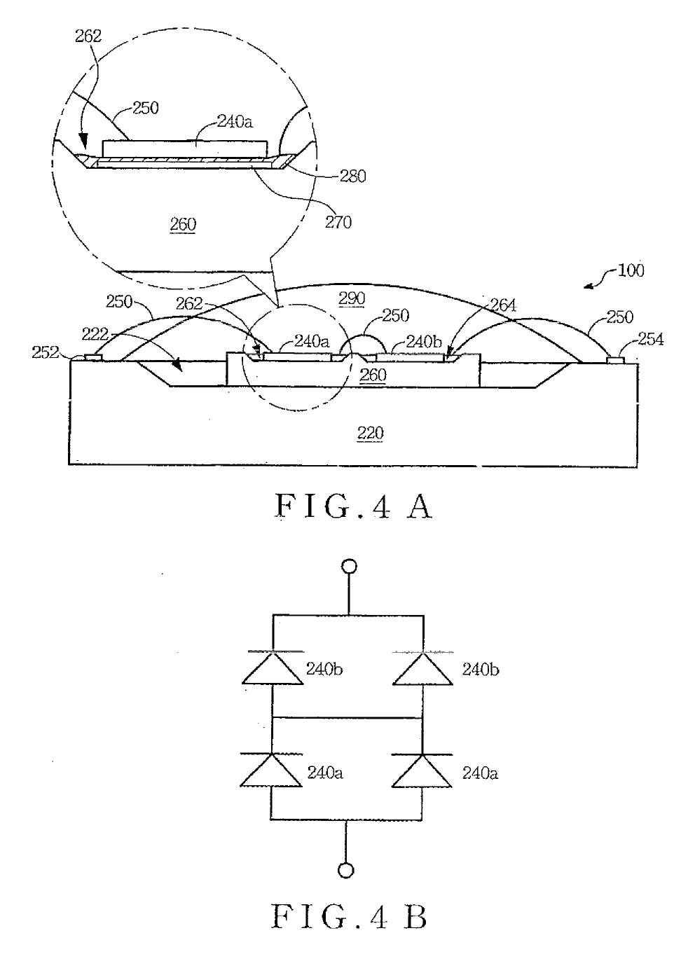

FIG. 4 is top view of another preferred embodiment of the multi-chip LED package 200 in the present invention. FIG. 4A is a cross-section view of the multi-chip LED package in FIG. 4 along cross section b-b. As shown, the multi-chip LED package 200 has a board 220, a plurality of LED chips 240a,240b (four LED chips 240a,240b are shown in this figure), a substrate 260, a plurality of conductive paste layers 280, and a passivation layer 290. The board 220 has a circular concave 222 thereon. The substrate 260 is located in the concave 222 and has a first hollow area 262 and a second hollow area 264 thereon.

The first hollow area 262 and the second hollow area 264 are rectangular in shape and evenly arranged on the substrate 260. Independent conductive patterns 270 are formed on the bottom surfaces of the first hollow area 262 and the second hollow area 264 respectively. Each of the hollow areas 262, 264 has two LED chips 240a,240b assembled therein. The plurality of the conductive paste layers 280 are pasted on the bottom surface of the first hollow area 262 and the second hollow area 264 for fixing the LED chips 240a,240b, respectively. The conductively paste layers 280 are also capable to electrically connect the negative electrode of the LED chips 240a,240b to the respected conductive patterns 270. The passivation layer 290 is deposited on the substrate 260 and filled into the hollow areas 262,264 to prevent the LED chips 240a,240b from the intrusion of the environment particles and moisture,

It is noted that the negative electrodes of the LED chips 240a,240b in each hollow areas 262,264 are electrically connected to the same conductive patterns 270 through the conductive paste layers 280 respectively. In addition, the positive electrodes of the two LED chips 240a assembled in the first hollow area 262 are electrically connected to a high level end 252 by using wires 250, the positive electrodes of the two LED chips 240b assembled in the second hollow area 264 are electrically connected to the conductive pattern 270 in the first hollow area 262 by using wires 250, and the negative electrodes of the two LED chips 240b are electrically connected to a low level end by using wires 250. That is, the LED chips 240a in the first hollow area 262 are connected in parallel, the LED chips 240b in the second hollow area 264 are connected in parallel, and the LED chip 240a in the first hollow area 262 is connected to the LED chip 240b in the second hollow area 264 in serial. The circuit diagram of the LED chips 240a,240b is shown in FIG. 4B.

In the present embodiment, the flowing of the conductive paste layer 280 pasted on the bottom of the hollow areas 262, 264 respectively are restricted by the sidewalls of the hollow areas 262,264. That is, because the uncontrollable flowing of the conductive paste layer 280 is restricted in the hollow area 262, 264, the negative electrodes of the LED chip 240a in the first hollow area 262 and that of the LED chips 240b in the second hollow area 264 would be perfectly isolated to prevent the happening of short circuit.

In addition, the multi-chip LED package 100 in FIG. 3 has all the LED chips 140a,140b connected in serial. The damage of a single LED chip 140a or 140b would stop the current, and the other LED chips 140a,140b cannot be lighted. In contrast, referring to FIG, 4B, the damage of a single LED chip 240a or 240b in the multi-chip LED package 200 in FIG. 4 would not influence the illumination of the other LED chips 240a,240b.

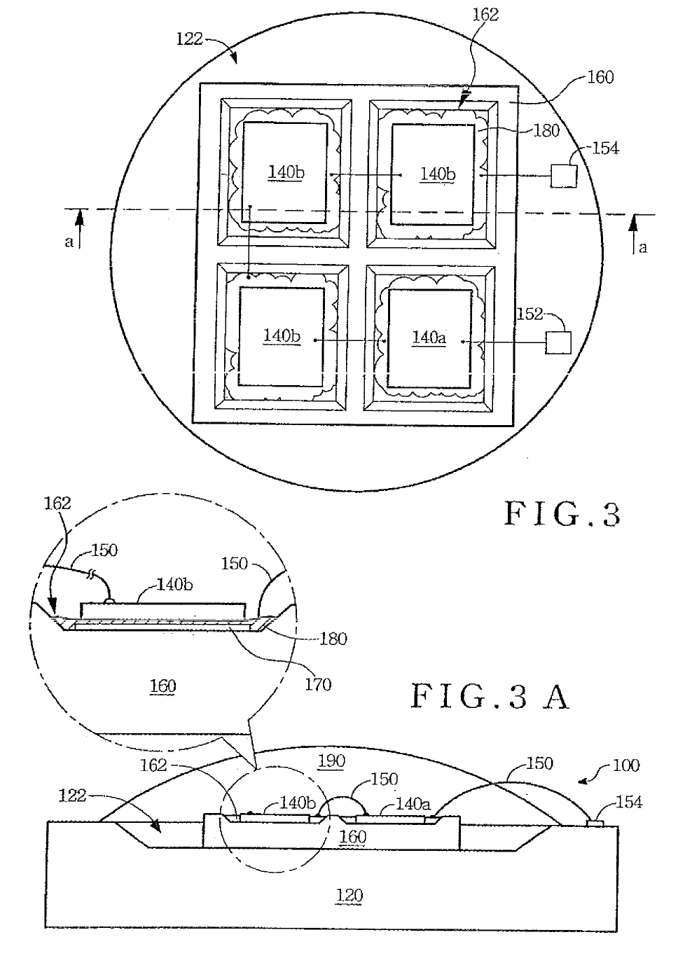

In the traditional multi-chip LED package 20 of FIG. 2, the overlapping of the conductive paste layer 26 may have the neighboring LED chips 12 electrically connected with each other to result short circuit. In contrast, referring to FIG. 3 of the present invention, the substrate 160 has hollow areas 162 formed thereon for locating the LED chips 140a,140b. The hollow areas 162 are capable of preventing the overflow of the conductive paste layer 180.

In addition, it is a traditional method to increase the interval between neighboring LED chips for preventing the unwanted influence of the flowing of the conductive paste layer. However, this method increases the size of the whole package and badly influences the focusing of illumination of the LED chips. In contrast, because the multi-chip LED package 100,200 of the present invention has hollow areas 162,164 formed on the substrate 160 for restricting the flowing of the conductive paste layers 180,280, the distance between neighboring hollow areas 162,164 can be reduced. Thus, the multi-chip LED package 100,200 in the present invention may prevent the problems of size increasing and the difficulty about illumination focusing of LED chips.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

I claim:

1. A multi-chip light emitting diode (LED) package comprising:
a plurality of LED chips; and
a substrate, having a plurality of conductive patterns formed thereon;
wherein each of the LED chips being assembled on the respected conductive pattern and electrically connected to the respected conductive pattern, and the LED chips are connected in serial through the conductive patterns.

2. The multi-chip LED package of claim 1, wherein the substrate has at least two hollow areas, and the conductive patterns are formed on a bottom surface of the hollow areas.

3. The multi-chip LED package of claim 1, wherein the LED chip is fixed on the conductive pattern by using a conductive paste layer.

4. The multi-chip LED package of claim 1, wherein the LED chip is fixed on the conductive pattern by eutectic bonding.

5. The multi-chip LED package of claim 1, wherein the LED chip is fixed on the conductive pattern by using solder balls or gold balls.

6. The multi-chip LED package of claim 2, wherein each hollow area has at least two LED chips connected in parallel assembled thereon.

7. The multi-chip LED package of claim 6, wherein positive electrodes of the LED chips assembled in the same hollow area are electrically connected to a high level end or the conductive pattern on the bottom surface of the other hollow areas by using a wire, and the negative electrodes are electrically connected to the conductive pattern in the same hollow area through a conductive paste layer.

8. The multi-chip LED package of claim 1, wherein at least one of the LED chips has a positive electrode electrically connected to a high level end by using a wire.

9. The multi-chip LED package of claim 8, wherein the conductive pattern is electrically connected to the negative electrode of the LED chip through the conductive paste layer.

10. The multi-chip LED package of claim 9, wherein each of the hollow area has the conductive patterns formed thereon, and each conductive pattern is electrically connected to the positive electrode of the LED chip assembled in the other hollow area or a low level end.

11. The multi-chip LED package of claim 2, wherein the hollow areas are rectangular in shape and evenly arranged on the substrate.

12. The multi-chip LED package of claim 1, further comprising a board having a concave thereon, and the substrate is located in the concave.

13. The multi-chip LED package of claim 2, further comprising a passivation layer filled into the hollow area.

14. A multi-chip LED package comprising:
a plurality of LED chips;
a substrate, having at least a first hollow area and a second hollow area, and independent conductive patterns being formed on bottom surfaces of the first hollow area and the second hollow area respectively; and
a plurality of conductive paste layers, formed on the bottom surfaces of the first hollow area and the second hollow area respectively for fixing the LED chips and electrically connecting the LED chips to the respected conductive patterns;
wherein at least two of the LED chips connected in parallel are assembled in the first hollow area or the second hollow area.

15. The multi-chip LED package of claim 14, wherein positive electrodes of the LED chips assembled in the first hollow area are electrically connected to a high level end by using wires, and positive electrodes of the LED chips assembled in the second hollow area are electrically connected to the conductive pattern in the first hollow area by using wires.

16. The multi-chip LED package of claim 15, wherein the conductive pattern in the second concave is electrically connected to a low level end.

17. The multi-chip LED package of claim 14, wherein the first hollow area and the second hollow area are rectangular in shape and evenly arranged in the substrate.

18. The multi-chip LED package of claim 14, further comprising a board having a concave, and the substrate is located in the concave.

19. The multi-chip LED package of claim 14, further comprising a passivation layer filled into the first hollow area and the second hollow area.
